(19) United States
(12) Patent Application Publication
(10) Pub. No.: US 2026/0171172 A1
(43) Pub. Date: Jun. 18, 2026

(54) MEMORY DEVICE, METHOD OF OPERATING THE DEVICE AND MEMORY SYSTEM

(71) Applicant: SAMSUNG ELECTRONICS CO., LTD., Suwon-si (KR)

(72) Inventors: Jung LEE, Suwon-si (KR); Yo Han LEE, Suwon-si (KR); Jin-Young KIM, Suwon-si (KR); Se Hwan PARK, Suwon-si (KR); Eun Hyang PARK, Suwon-si (KR); Tae Yun LEE, Suwon-si (KR)

(73) Assignee: SAMSUNG ELECTRONICS CO., LTD., Suwon-si (KR)

(21) Appl. No.: 19/385,637

(22) Filed: Nov. 11, 2025

(30) Foreign Application Priority Data
Dec. 12, 2024 (KR) 10-2024-0185304

(51) Int. Cl. G11C 16/34; G11C 16/10; G11C 16/32

(52) U.S. Cl. CPC G11C 16/3404; G11C 16/102; G11C 16/32

(57) ABSTRACT

A memory device may include a control hardware configured to control an operation of a memory cell array, wherein the control hardware is further configured to: receive a first program command for programming a plurality of memory cells; determine whether to check a threshold voltage of a second ground selection transistor based on the first program command; compare variation of the threshold voltage of the second ground selection transistor with a reference voltage based on determining to check the threshold voltage of the second ground selection transistor; and program the threshold voltage of the second ground selection transistor based on a result of the comparing.

### CROSS-REFERENCE TO RELATED APPLICATIONS

This application claims priority from Korean Patent Application No. 10-2024-0185304 filed on Dec. 12, 2024 in the Korean Intellectual Property Office, the disclosure of which is incorporated herein by reference in its entirety.

### BACKGROUND

### 1. Field

The present invention relates to a memory device, a method of operating the device, and a memory system.

### 2. Description of the Related Art

As technology advances, the integration density of memory devices increases. Therefore, three-dimensional semiconductor memory devices with three-dimensional arrays of transistors are being proposed. Various technologies for enhancing the degree of integration of such three-dimensional memory devices are being proposed, and technologies that may ensure the operational reliability of the memory devices with the enhancement of the degree of integration are being researched.

### SUMMARY

Aspects of the present invention provide a memory device having improved operational reliability, a method of operating the same, and a memory system.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more example embodiments, a memory device may include: a memory cell array including: a cell string including a plurality of memory cells connected to a bit line and a common source line; a first ground selection transistor having a first threshold voltage and configured to connect the common source line to the plurality of memory cells based on a voltage applied to a first ground selection line; and a second ground selection transistor having a second threshold voltage greater than the first threshold voltage, and configured to connect the common source line to the plurality of memory cells based on a voltage applied to a second ground selection line. The memory device may further include a control hardware configured to control an operation of the memory cell array, wherein the control hardware is further configured to: receive a first program command for programming the plurality of memory cells; determine whether to check a threshold voltage of the second ground selection transistor based on the first program command; compare variation of the threshold voltage of the second ground selection transistor with a reference voltage based on determining to check the threshold voltage of the second ground selection transistor; and program the threshold voltage of the second ground selection transistor based on a result of the comparing.

According to one or more example embodiments, a method of operating a memory device including a cell string including a plurality of memory cells connected to a bit line and a common source line, a first ground selection transistor having a first threshold voltage and configured to connect the common source line to the plurality of memory cells based on a voltage applied to a first ground selection line, and a second ground selection transistor having a second threshold voltage greater than the first threshold voltage, and configured to connect the common source line to the plurality of memory cells based on a voltage applied to a second ground selection line, may include: receiving a first program command for programming the plurality of memory cells; determining whether to check the threshold voltage of the second ground selection transistor based on the first program command; comparing variation of the threshold voltage of the second ground selection transistor with a reference voltage based on determining to check; and programming the threshold voltage of the second ground selection transistor based on a result of the comparing.

According to one or more example embodiments, a memory system may include: a cell string including a plurality of memory cells connected to a bit line and a common source line; a first ground selection transistor having a first threshold voltage and configured to connect the common source line to the plurality of memory cells based on a voltage applied to a first ground selection line; and a second ground selection transistor having a second threshold voltage greater than the first threshold voltage, and configured to connect the common source line to the plurality of memory cells based on a voltage applied to a second ground selection line. The memory system may further include a memory controller configured to control operation of a memory device, wherein the memory controller is further configured to: receive a program command for programming the plurality of memory cells; and determine whether to check the threshold voltage of the second ground selection transistor based on the program command. The memory device is configured to: compare variation of the threshold voltage of the second ground selection transistor with a reference voltage based on the memory controller determining to check the threshold voltage of the second ground selection transistor; and program the threshold voltage of the second ground selection transistor based on a result of the comparing.

### BRIEF DESCRIPTION OF THE DRAWINGS

The above and other aspects and features of the present disclosure will become more apparent by describing in detail exemplary embodiments thereof referring to the attached drawings, in which:

FIG. 1 is a block diagram of a memory system according to one or more embodiments;

FIG. 2 is a circuit diagram showing a memory block included in a memory device according to one or more embodiments;

FIG. 3 is a circuit diagram for explaining the configuration of the memory block included in the memory device according to one or more embodiments:

FIG. 4 is a circuit diagram showing cell strings of the memory device to explain a cell string selection operation according to one or more embodiments;

FIG. 5 is a diagram showing variation of ground selection transistors according to one or more embodiments;

FIG. 6 is a diagram showing a change in variation of the ground selection transistors over time according to one or more embodiments;

FIG. 7 is a flowchart for explaining an operation of the memory system according to one or more embodiments;

FIG. 8 is a diagram for explaining the operation of FIG. 7 according to one or more embodiments;

FIG. 9 is a diagram for explaining the operation of FIG. 7 according to one or more embodiments;

FIG. 10 is a diagram for explaining the operation of FIG. 7 according to one or more embodiments;

FIG. 11 is a diagram for explaining the operation of FIG. 7 according to one or more embodiments;

FIG. 12 is a diagram for explaining the operation of FIG. 7 according to one or more embodiments;

FIG. 13 is a flowchart for explaining the operation of the memory system according to one or more embodiments;

FIG. 14 is a flowchart for explaining the operation of the memory system according to one or more embodiments;

FIG. 15 is a diagram for explaining the operation of FIG. 14 according to one or more embodiments;

FIG. 16 is a flowchart for explaining the operation of the memory system according to one or more embodiments; and

FIG. 17 is a block diagram of an electronic device according to one or more embodiments.

### DETAILED DESCRIPTION OF THE EMBODIMENTS

Hereinafter, embodiment according to the technical idea of the present disclosure will be described referring to the accompanying drawings.

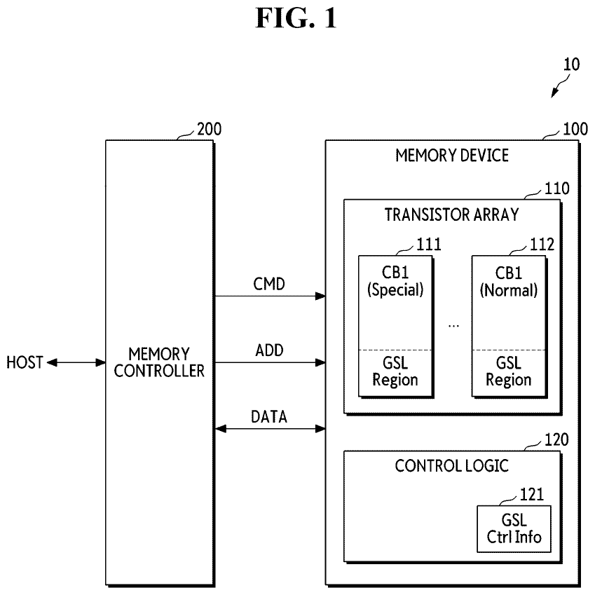

FIG. 1 is a block diagram of a memory system according to one or more embodiments.

Referring to FIG. 1, a memory system 10 may include a memory device 100 and a memory controller 200. The memory device 100 may include a transistor array 110 and control logic 120. The memory device 100 may further include a voltage generator that generates various voltages associated with program, read, and erase operations of data, a page buffer connected to the transistor array 110 through bit lines, and various other components. In one or more embodiments, the transistor array 110 may be a memory cell array.

In one or more embodiments, the memory device 100 may include a non-volatile memory device. For example, the memory device 100 may include a non-volatile memory device such as a NAND flash memory, a Vertical NAND flash memory, a NOR flash memory, a resistive random access memory, a phase-change memory or a magnetoresistive random access memory.

In one or more embodiments, the memory device 100 or the memory system 10 may be implemented as an embedded memory equipped in the electronic device, or may be implemented as an external memory attachable to and detachable from the electronic device.

For example, the memory device 100 or the memory system 10 may be implemented in various forms, such as an embedded universal flash storage (UFS) memory device, an embedded multi-media card (eMMC), a solid state drive (SSD), a UFS memory card, a compact flash (CF), a secure digital (SD), a micro secure digital (Micro-SD), a mini secure digital (Mini-SD), an extreme digital (xD), and a memory stick.

The memory controller 200 may control the memory device 100 to read data stored in the memory device 100 or write data to the memory device 100 (or program) in response to write and read requests from the host HOST. For example, the memory controller 200 may control program, read and erase operations on the memory device 100 by providing an address ADD and a command CMD to the memory device 100. In addition, data DATA to be written to the memory device 100 and data DATA read from the memory device 100 may be exchanged between the memory controller 200 and the memory device 100.

The transistor array 110 may include a plurality of cell blocks CB1 to CBN. When the memory device 100 is a vertical NAND flash memory device, each of the plurality of cell blocks CB1 to CBN may include a plurality of cell strings. For example, a plurality of cell strings may be connected to any one bit line, and a selected any one of the plurality of cell strings may be electrically connected to the bit line at the time of data program and read operation.

The plurality of cell blocks CB1 to CBN may store various types of data. For example, the plurality of cell blocks CB1 to CBN may include special cell blocks 111 that store various pieces of information other than user data, and normal cell blocks 112 that store user data.

In one or more embodiments, the normal cell blocks 112 and the special cell blocks 111 may be implemented to have different structures or may be driven on the basis of different methods. In one or more embodiments, the special cell blocks 111 may store various pieces of information associated with security. However, the embodiments are not limited thereto.

In one or more embodiments, each of the plurality of cell blocks CB1 to CBN may include a ground selection line GSL region in which a plurality of ground selection lines GSL are disposed. If a first cell block CB1 corresponds to the special cell block 111 and a Nth cell block CBN corresponds to the normal cell block 112, each of the first cell block CB1 and the Nth cell block CBN may include a GSL region.

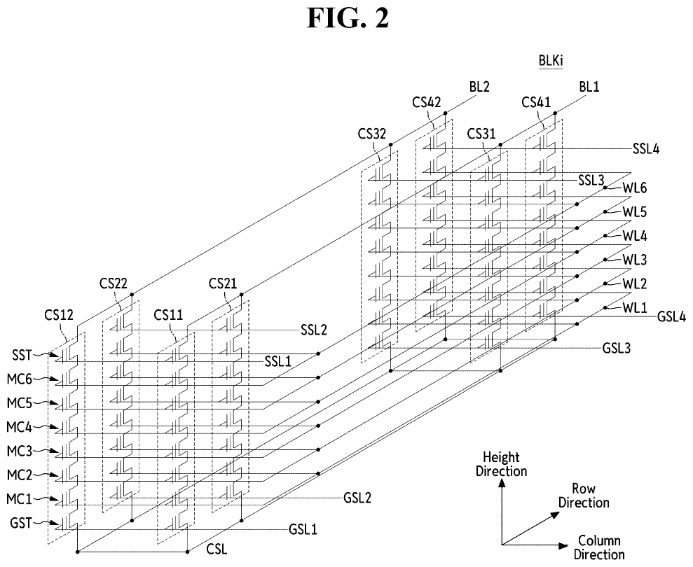

As described above, the GSL region of the first cell block CB1 and the GSL region of the Nth cell block CBN may have physically different structures from each other. For example, the GSL region of the first cell block CB1 and the Nth cell block CBN may be managed differently from each other, and the management on the plurality of ground selection transistors (e.g., GST of FIG. 2) connected to the ground selection lines disposed in the GSL region of the first cell block CB1, and the management on the plurality of ground selection transistors GST connected to the ground selection lines disposed in the GSL region of the Nth cell block CBN may be performed to be different from each other.

For example, the plurality of ground selection transistors GST provided in each of the plurality of cell blocks CB1 to CBN may be programmed to have a predetermined threshold voltage, and the threshold voltages of the ground selection transistors GST disposed in the GSL region of the first cell block CB1 and the ground selection transistors GST disposed in the GSL region of the Nth cell block CBN may be programmed to be different from each other.

Meanwhile, in one or more embodiments, the control logic 120 (control hardware) may include GSL control information 121. For example, the control logic 120 may include a predetermined storage circuit for storing information such as a fuse circuit and an anti-fuse circuit, and may perform a program operation on the plurality of ground selection transistors GST of the plurality of cell blocks CB1 to CBN on the basis of the GSL control information 121.

In one or more embodiments, in the process of manufacturing the memory device 100, the GSL control information 121 may be implemented to be stored in the storage circuit of the control logic 120, and the GSL control information 121 may be provided as the control logic 120 in the initial driving process of the memory device 100.

FIG. 2 is a circuit diagram showing a memory block included in the memory device according to one or more embodiments.

Referring to FIG. 2, a memory block BLKi may include a plurality of cell strings CS11 to CS41 and CS12 to CS42. The plurality of cell strings CS11 to CS41 and CS12 to CS42 may be arranged along a row direction and a column direction to form rows and columns.

Each cell string may include a ground selection transistor GST, memory cells MC1 to MC6, and a string selection transistor SST. The ground selection transistors GST, the memory cells MC1 to MC6, and the string selection transistors SST of each cell string may be stacked, for example, in a height direction perpendicular to the substrate.

Each of the rows of the plurality of cell strings CS11 to CS41 and CS12 to CS42 is connected to different string selection lines SSL1 to SSL4 from each other. For example, the string selection transistors SST of the cell strings CS11 and CS12 are commonly connected to the string selection line SSL1. The string selection transistors SST of the cell strings CS21 and CS22 are commonly connected to the string selection line SSL2. The string selection transistors SST of the cell strings CS31 and CS32 are commonly connected to the string selection line SSL3. The string selection transistors SST of the cell strings CS41 and CS42 are commonly connected to the string selection line SSL4.

Each of the columns of the plurality of cell strings CS11 to CS41 and CS12 to CS42 is connected to different bit lines BL1 and BL2 from each other. For example, the string selection transistors SST of the cell strings CS11 to CS41 are commonly connected to the bit line BL1. The string selection transistors SST of the cell strings CS12 to CS42 are commonly connected to the bit line BL2.

Each of the rows of the plurality of cell strings CS11 to CS41 and CS12 to CS42 is connected to different ground selection lines GSL1 to GSL4 from each other. For example, the ground selection transistors GST of the cell strings CS11 and CS12 are commonly connected to a ground selection line GSL1. The ground selection transistors GST of the cell strings CS21 and CS22 are commonly connected to a ground selection line GSL2. The ground selection transistors GST of the cell strings CS31 and CS32 are commonly connected to a ground selection line GSL3. The ground selection transistors GST of the cell strings CS41 and CS42 are commonly connected to a ground selection line GSL4.

Memory cells located at the same height from the substrate (or the ground selection transistors GST) are commonly connected to one word line, and each of the memory cells located at different heights may be connected to different word lines WL1 to WL6 from each other.

For example, memory cells MC1 are commonly connected to the word line WL1. Memory cells MC2 are commonly connected to the word line WL2. Memory cells MC3 are commonly connected to the word line WL3. Memory cells MC4 are commonly connected to the word line WL4. Memory cells MC5 are commonly connected to the word line WL5. Memory cells MC6 are commonly connected to the word line WL6.

The ground selection transistors GST of the cell strings CS11 to CS41 and CS12 to CS42 are commonly connected to a common source line CSL.

Although FIG. 2 shows an exemplary memory block BLKi, the embodiments are not limited to the memory block BLKi shown in FIG. 2. For example, the number of rows of the cell strings may increase or decrease. Furthermore, as the number of rows of cell strings changes, the number of string selection lines connected to the rows of cell strings and the number of cell strings connected to one bit line may also change. As the number of rows of the cell strings changes, the number of ground selection lines connected to the rows of cell strings may also change.

The number of columns of the cell strings may increase or decrease. As the number of columns of the cell strings changes, the number of bit lines connected to the columns of the cell strings and the number of cell strings connected to one string selection line may also change.

In one or more embodiments, the height of the cell strings may increase or decrease. For example, the number of memory cells stacked in each of the cell strings may increase or decrease, unlike that shown. As the number of memory cells stacked in each of the cell strings changes, the number of word lines may also change. For example, the number of string selection transistors or ground selection transistors provided in each of the cell strings may increase. As the number of string selection transistors or ground selection transistors provided in each of the cell strings changes, the number of string selection lines or ground selection lines may also change. When the number of string selection transistors or ground selection transistors increases, the string selection transistors or the ground selection transistors may be stacked in the same form as the memory cells MC1 to MC6.

For example, write and read operations on the memory device may be performed in units of rows of the cell strings CS11 to CS41 and CS12 to CS42. The cell strings CS11 to CS41 and CS12 to CS42 are selected in units of one row by the ground selection lines CSL1 to GSL4, and the cell strings CS11 to CS41 and CS12 to CS42 may be selected in units of one row by the string selection lines SSL1 to SSL4.

In addition, a voltage may be applied to the ground selection lines GSL1 to GSL4 with at least two ground selection lines GSL1 to GSL2 or GSL3 to GSL4 as a single unit. In addition, a voltage may be applied to the ground selection lines GSL1 to GSL4 with the entire ground selection lines GSL1 to GSL4 as a single unit.

In one or more embodiments, the ground selection transistors GST connected to the ground selection lines GSL1 to GSL4 may be programmed to have a preset threshold voltage.

In the selected rows of the cell strings CS11 to CS41 and CS12 to CS42, writing and reading may be performed in units of a page. The page may be one row of the memory cells connected to one word line. In a selected row of cell strings CS11 to CS41 and CS12 to CS42, the memory cells may be selected in units of a page by the word lines WL1 to WL6.

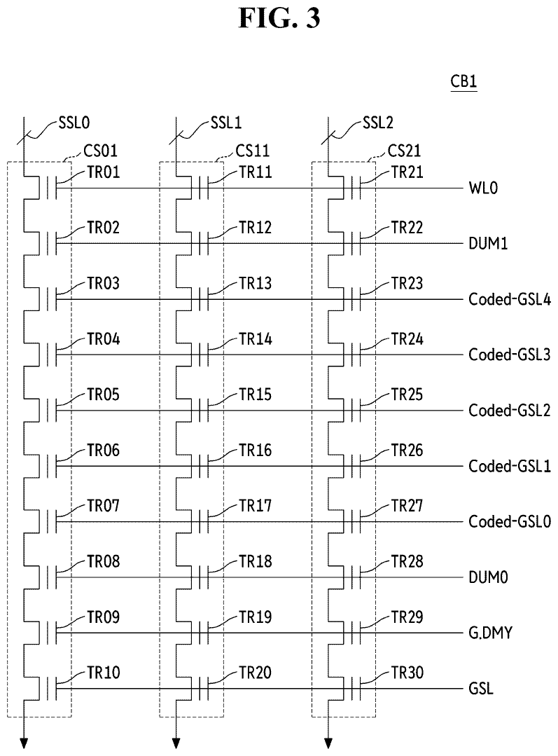

FIG. 3 is a circuit diagram showing a configuration of a memory block included in the memory device according to one or more embodiments.

Hereinafter, although a first cell memory block CB1 among the memory blocks will be described as an example, the cell blocks included in the memory device 100 are not limited thereto, and the memory device 100 may further include a plurality of cell blocks. In one or more embodiments that memory device may be a three-dimensional memory device.

Referring to FIG. 3, the first cell block CB1 includes a plurality of cell string regions CS01, CS11 and CS21, and each of the cell string regions CS01, CS11 and CS21 may be connected to the string selection lines SSL0, SSL1 and SSL2. For example, the first cell block CB1 may include a first cell string region CS01, a second cell string region CS11, and a third cell string region CS21. However, the number of cell string regions is not limited thereto, and the first cell block CB1 may further include a plurality of cell string regions.

The first cell string region CS01 may be connected to the first string selection line SSL0, the second cell string region CS11 may be connected to the second string selection line SSL1, and the third cell string region CS21 may be connected to the third string selection line SSL2.

In one or more embodiments, the cell string regions CS01, CS11, and CS21 may include a plurality of transistors TR01 to TR29. For example, the cell string regions CS01, CS11, and CS21 may be made up of a plurality of transistors TR01 to TR29.

The first cell string region CS01, the second cell string region CS11, and the third cell string region CS21 may be connected through word lines. For example, each of the transistors of the first cell string region CS01, the second cell string region CS11, and the third cell string region CS21 may be connected to different word lines from each other.

In one or more embodiments, the ground selection line GSL may activate transistors included in any cell string region. For example, when any cell string selection line SSL activates any cell string, the transistors of the region connected to the ground selection line GSL may be activated.

In one or more embodiments, some of the word lines may be made up of ground selection lines Coded-GSL0, Coded-GSL1, Coded-GSL2, Coded-GSL3, and Coded-GSL4 with ground selection functions programmed thereon. For example, each of the programmed ground selection lines Coded-GSL0, Coded-GSL1, Coded-GSL2, Coded-GSL3, and Coded-GSL4 may be programmed such that the transistors (e.g., ground selection transistors) connected to them have different threshold voltages, and may control whether the transistors of each cell string region are activated.

In one or more embodiments, the dummy line DUM0 may be present between the programmed ground selection lines Coded-GSL0, Coded-GSL1, Coded-GSL2, Coded-GSL3, and Coded-GSL4 and the adjacent word line WL0. In one or more embodiments, a ground dummy line G. DMY may be present between the programmed ground selection lines Coded-GSL0, Coded-GSL1, Coded-GSL2, Coded-GSL3, and Coded-GSL4 and the ground selection line GSL. Because the ground dummy line G. DMY and the dummy line DUM0 are present, the memory device 100 may perform stable ground selection line programming.

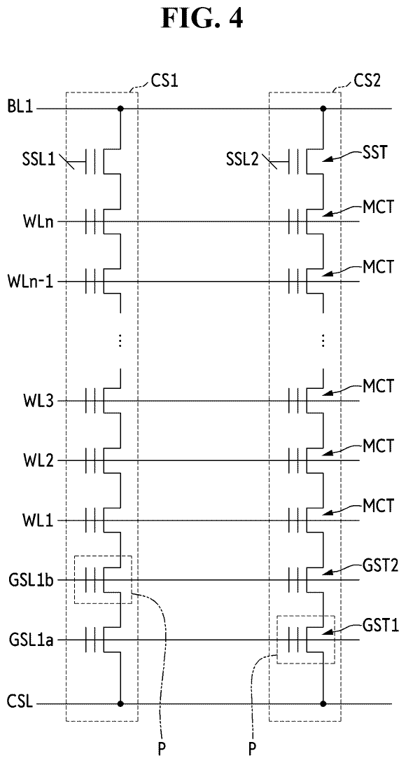

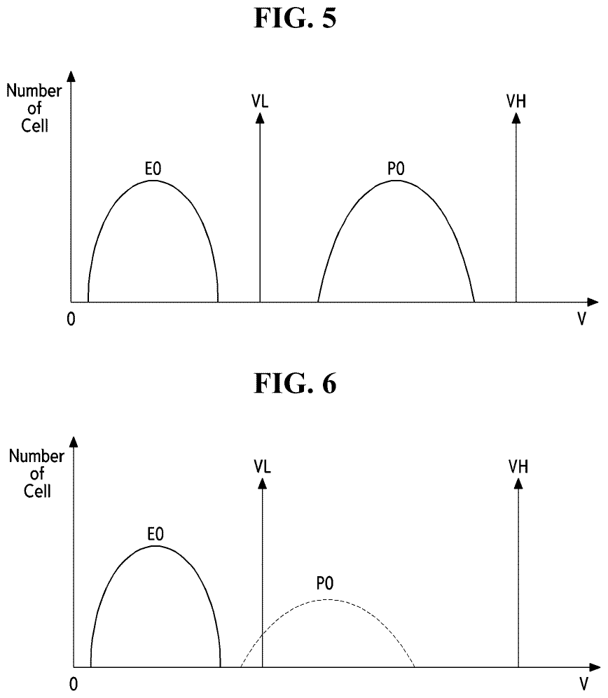

FIG. 4 is a circuit diagram showing cell strings of a memory device to explain a cell string selection operation. FIG. 5 is a diagram showing the variation of the ground selection transistors.

Referring to FIGS. 4 and 5, the first and second cell strings CS1 and CS2 may be connected in parallel between one bit line BL1 and a common source line CSL.

The string selection transistor SST of the first cell string CS1 may be controlled by a first string selection line SSL1, and the string selection transistor SST of the second cell string CS2 may be controlled by the second string selection line SSL.

In each of the first and second cell strings CS1 and CS2, the first and second ground selection transistors GST1 and GST2 may be programmed to have different threshold voltages from each other. That is, the first and second ground selection transistors GST1 and GST2 may be programmed to have different threshold voltages from each other, using the programmed ground selection lines GSL1b and GSL1a.

For example, the ground selection transistors GST1 and GST2 designated with “P” represent the ground selection transistors GST1 and GST2 programmed with the second threshold voltage P0.

In the first cell string CS1, the first ground selection transistor GST1 may have a first threshold voltage E0, and the second ground selection transistor GST2 may have a second threshold voltage P0 greater than the first threshold voltage.

In the second cell string CS2, the first ground selection transistor GST1 may have the second threshold voltage P0, and the second ground selection transistor GST2 may have the first threshold voltage E0. That is, the first ground selection transistors GST1 of the first and second cell strings CS1 and CS2 may have different threshold voltages from each other, and the second ground selection transistors GST2 of the first and second cell strings CS1 and CS2 may have different threshold voltages from each other.

The first ground selection transistor GST1 of the first cell string CS1 and the second ground selection transistor GST2 of the second cell string CS2 may be turned on by a first operating voltage VL that is greater than the first threshold voltage E0 and less than the second threshold voltage P0.

The second ground selection transistor GST2 of the first cell string CS1 and the first ground selection transistor GST1 of the second cell string CS2 may be turned on by a second operating voltage VH that is greater than the second threshold voltage P0.

In one or more embodiments, the first ground selection transistors GST1 of the first and second cell strings CS1 and CS2 commonly connected to the first programmed ground selection line GSL1a may operate differently depending on the voltage applied to the first programmed ground selection line GSL1a.

Further, the second ground selection transistors GST2 of the first and second cell strings CS1 and CS2 commonly connected to the second programmed ground selection line GSL1b may operate differently depending on the voltage applied to the second programmed ground selection line GSL1b.

The electrical connection between the first bit line BL1 and the first and second cell strings CS1 and CS2 may be controlled depending on the voltage applied to the first and second string selection lines SSL1 and SSL2.

The electrical connection between the first and second cell strings CS1 and CS2 and the common source line CSL may be controlled depending on the voltages applied to the first and second programmed ground selection lines GSL1a and GSL1b.

In one or more embodiments, in the first and second cell strings CS1 and CS2 connected to the first bit line BL1, even if the first and second programmed ground selection lines GSL1a and GSL1b are physically connected in common to the first and second cell strings CS2 and CS2, the first and second ground selection transistors GST1 and GST2 of the first and second cell strings CS1 and CS2 may be electrically separated from each other,.

For example, a power supply voltage Vcc may be applied to the first string selection line SSL1, a ground voltage may be applied to the second string selection line SSL2, a second operating voltage VH may be applied to the second programmed ground selection line GSL1b, and a first operating voltage VL may be applied to the first programmed ground selection line GSL1a.

In this case, since both the first and second ground selection transistors GST1 and GST2 included in the first cell string CS1 are turned on, the first bit line BL1 and the common source line CLS may be electrically connected through the first cell string CS1.

However, since the second ground selection transistor GST2 included in the second cell string CS2 is not turned on, the second cell string CS2 may be electrically separated from the first bit line BL1 and the common source line CSL and may be in a floating state. That is, the unselected second cell string CS2 may be electrically separated from the first bit line BL1 and the common source line CSL. This may prevent a read disturbance phenomenon from occurring in the unselected cell string CS2 among the cell strings CS1 and CS2 connected to the selected bit line BL1 at the time of the read operation on the memory cell array.

In one or more embodiments, the memory cells (e.g., the memory cells MCT connected to WL3 to WLn-2) disposed at the center of the first and second cell strings CS1 and CS2 may be a TLC (triple level cell) or QLC (quad level cell) that stores have 3 bits or more. The memory cells (e.g., the memory cells MCT connected to WL1 to WL2 or WLn-1 to WLn) disposed at the edges of the first and second cell strings CS1 and CS2 may be multi-level cells (MLC) or single-level cells (SLC) that store 2 bits or less. However, the embodiments are not limited thereto, and the programming method of the memory cells MCT may be modified as desired.

FIG. 6 is a diagram showing a variation change of the ground selection transistor over time.

Referring to FIG. 6, the variation of the ground selection transistors GST1 and GST2 (e.g., the ground selection transistors GST1 and GST2 indicated by “P” of FIG. 4) having the second threshold voltage P0 may change as shown over time.

In this case, because the ground selection transistors GST1 and GST2 having the second threshold voltage P0 may be turned on by the first operating voltage VL, the above-mentioned operation may not be reliably performed.

On the other hand, the operation of checking such a variation and reprogramming the ground selection transistors GST1 and GST2 may be performed, for example, while the memory block is being erased. In this case, since there is generally a considerable time for the memory to perform read and write operations between block erase operations, it is also difficult to ensure the operational reliability during that time. In addition, for example, if the operation of reprogramming the ground selection transistors GST1 and GST2 is performed while the memory block is being erased, it is also difficult to comply with the specifications that stipulate the erase time.

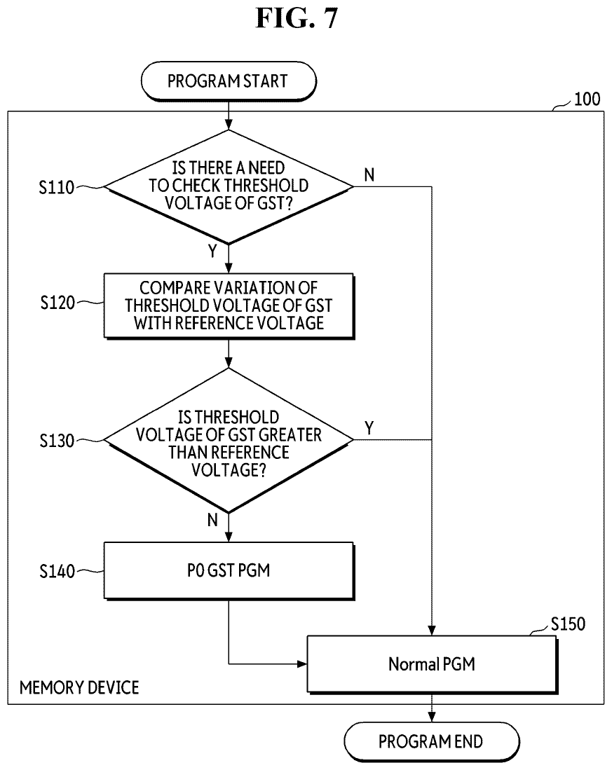

Therefore, the operation of the memory system for ensuring the operational reliability of the memory device will be described referring to FIGS. 7 to 16.

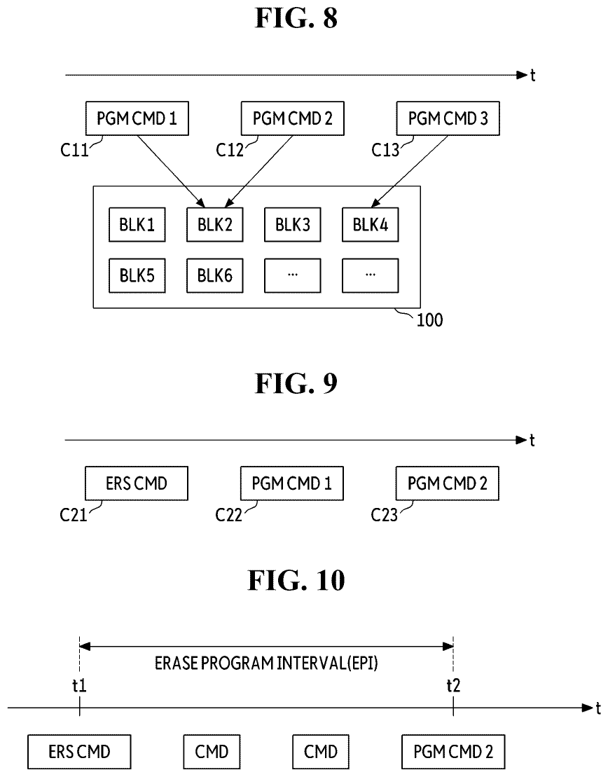

FIG. 7 is a flowchart for explaining the operation of the memory system according to one or more embodiments. FIGS. 8 to 12 are diagrams for explaining the operation of FIG. 7.

For example, the operation shown in FIG. 7 may be performed by the control logic (120 of FIG. 1) of the memory device 100. That is, the operation of the memory device 100 described below may be the operation of the control logic (120 of FIG. 1) of the memory device 100. However, embodiments are not limited thereto, and other configurations of the memory device 100 may perform the operations described below as needed.

Referring to FIG. 7, a program operation is initiated. For example, the memory device 100 may be provided with a program command and an address to which data is to be programmed from the memory controller (200 of FIG. 1) to initiate the program operation.

In one or more embodiments, the program command received by the memory device 100 may be, for example, a command for instructing to program data to the memory cells MCT connected to WL1 to WLn shown in FIG. 4.

Next, it is determined whether to check the threshold voltage of the ground selection transistor (hereinafter, P0 GST) having the threshold voltage of P0 described above in response to the program command (S110).

If it is determined not to check the threshold voltage of the P0 GST (S110-N), the program on the P0 GST is not performed. Instead a normal program, in which data is programmed to the memory cells MCT connected to WL1 to WLn shown in FIG. 4 in accordance with the program command, is performed (S150).

If it is determined to check the P0 GST (S110-Y), the threshold voltage variation of the P0 GST is compared with a reference voltage (S120).

In one or more embodiments, whether to check the threshold voltage of the P0 GST may be determined in various ways.

For example, the memory device 100 may determine whether to check the threshold voltage of the P0 GST based on whether the block address of the data to be programmed through the currently received program command is identical to the block address of the data to be programmed through the program command received before the present time point.

For example, referring to FIG. 8, if the memory device 100 receives the program command C12 at the present time point, the block address BLK2 of the data to be programmed through the currently received program command C12 is identical to the block address BLK2 of the data to be programmed through the program command C11 received before the present time point. In this case, the memory device 100 may determine that the threshold voltage of the P0 GST does not need to be checked.

Next, if the memory device 100 receives the program command C13 at the present time point, the block address BLK4 of the data to be programmed through the currently received program command C13 is not identical to the block address BLK2 of the data to be programmed through the program command C12 received before the present time point. In this case, the memory device 100 may determine to check the threshold voltage of the P0 GST.

Furthermore, for example, the memory device 100 may determine whether to check the threshold voltage of the P0 GST based on whether the command received before the currently received program command is an erase command.

For example, referring to FIG. 9, if the memory device 100 receives a program command C22 at the present time point, because the command received before the currently received program command C22 is an erase command C21, the memory device 100 may determine that the threshold voltage of P0 GST does not need to be checked.

Next, if the memory device 100 receives the program command C23 at the present time point, because the command received before the currently received program command C23 is not an erase command C21, the memory device 100 may determine to check the threshold voltage of P0 GST.

Furthermore, for example, the memory device 100 may compare an interval between the currently received program command and the previously received erase command with a reference time to determine whether to check the threshold voltage of P0 GST.

For example, referring to FIG. 10, when the memory device 100 receives a program command PGM CMD at a present time point t2, the memory device 100 calculates the interval (EPI; Erase Program Interval) from the time point t1 at which the erase command ERS CMD is received to the present time point t2, and if the interval is equal to or less than a reference time, the memory device 100 may determine that the threshold voltage of P0 GST does not need to be checked.

In contrast, if the EPI is equal to or greater than the reference time, the memory device 100 may determine to check the threshold voltage of P0 GST.

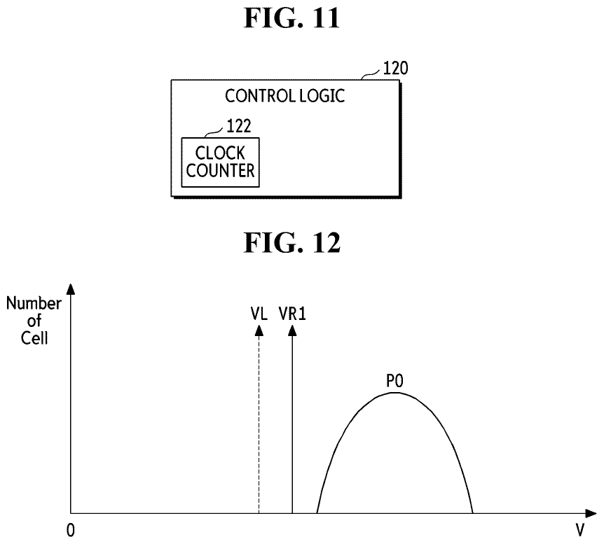

Referring to FIG. 11, the control logic 120 of the memory device may include a clock counter 122 for the interval calculation.

The control logic 120 may count the number of clocks (cycles) between the erase command (ERS CMD of FIG. 10) and the program command (PGM CMD of FIG. 10) using the clock counter 122, and compare the counted number of cycles with the reference number of cycles to determine whether to check the threshold voltage of the P0 GST.

For example, if the counted number of cycles is equal to or less than the reference number of cycles, the control logic 120 may determine that the threshold voltage of the P0 GST does not need to be checked. Conversely, if the counted number of cycles is equal to or greater than the reference number of cycles, the control logic 120 may determine to check the threshold voltage of the P0 GST.

Also, for example, if a flag is provided from the memory controller (200 of FIG. 1), the memory device 100 may determine to check the threshold voltage of the P0 GST. Conversely, if a flag is not provided from the memory controller (200 of FIG. 1), the memory device 100 may determine not to check the threshold voltage of the P0 GST.

Referring to FIG. 7 again, when the memory device 100 compares the threshold voltage variation of the P0 GST with the reference voltage (S120), the reference voltage may be greater than the first operating voltage (VL of FIG. 6) described above.

Referring to FIG. 12, the memory device 100 may compare whether the threshold voltage variation of the P0 GST is equal to or greater than a reference voltage VR1 that is greater than the first operating voltage VL.

Referring to FIG. 7 again, if the threshold voltage variation of the P0 GST is greater than the reference voltage (S130-Y), a program may not be performed on the P0 GST. Therefore, a normal program for programming the data in accordance with the program command without performing the program on GST is performed (S150).

If the threshold voltage variation of P0 GST is not greater than the reference voltage (S130-N), the program for controlling the variation is performed on P0 GST (S140). Further, the normal program for programming the data in accordance with the program command is performed (S150).

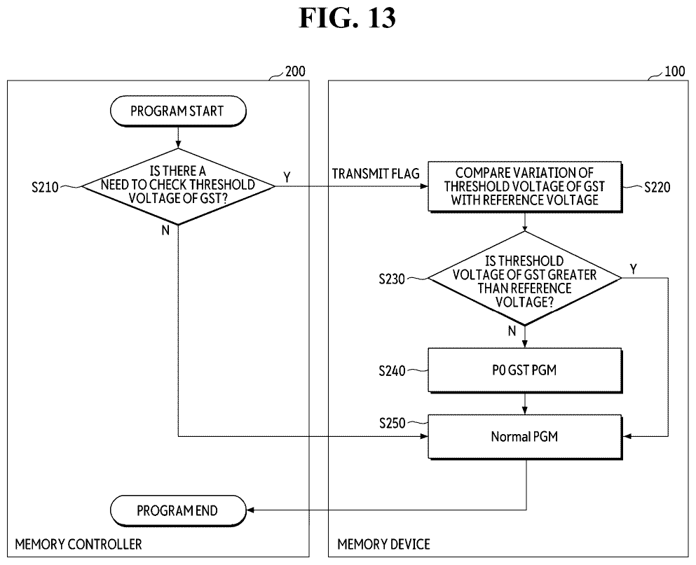

FIG. 13 is a flow chart for explaining the operation of a memory system according to one or more embodiments.

Referring to FIG. 13, a program operation is started. For example, the memory controller 200 may be provided with a program command and an address to which data is to be programmed from an external host, and start the program operation.

In one or more embodiments, the program command received by the memory controller 200 may be, for example, a command for instructing to program the data into the memory cells MCT connected to WL1 to WLn shown in FIG. 4 of the memory device 100.

Next, the memory controller 200 determines whether to check the threshold voltage of the P0 GST based on the program command (S210).

A method for determining whether the memory controller 200 needs to check the threshold voltage of P0 GST may be similar to the method for determining whether the memory device 100 needs to check the threshold voltage of the P0 GST, and the repeated description will not be provided.

If the memory controller 200 determines that the threshold voltage of the P0 GST does not need to be checked (S210-N), it does not instruct the memory device 100 to perform the program on the P0 GST, but instructs the memory device 100 to perform a normal program according to a program command, and causes the memory device 100 to perform the normal program (S250).

If the memory controller 200 determines to check the P0 GST (S210-Y), it transmits a flag for instructing to compare the threshold voltage variation of the P0 GST with the reference voltage to the memory device 100. The memory device 100 compares the threshold voltage variation of the P0 GST with the reference voltage in response thereto (S220).

If the threshold voltage variation of the P0 GST is greater than the reference voltage (S230-Y), it is not necessary to perform the program on the P0 GST. Therefore, the memory device 100 does not perform the program on the P0 GST, but performs the normal program for programming the data in accordance with the program command (S250).

If the threshold voltage variation of P0 GST is not greater than the reference voltage (S230-N), the memory device 100 performs the program for controlling variation on P0 GST (S240). Further, after performing the normal program for programming the data in accordance with the program command (S250), the memory device 100 notifies the memory controller 200 that the program is completed.

The operations S220, S230, S240, and S250 of the memory device 100 are substantially the same as those in one or more embodiments described above, and therefore the repeated description will not be provided.

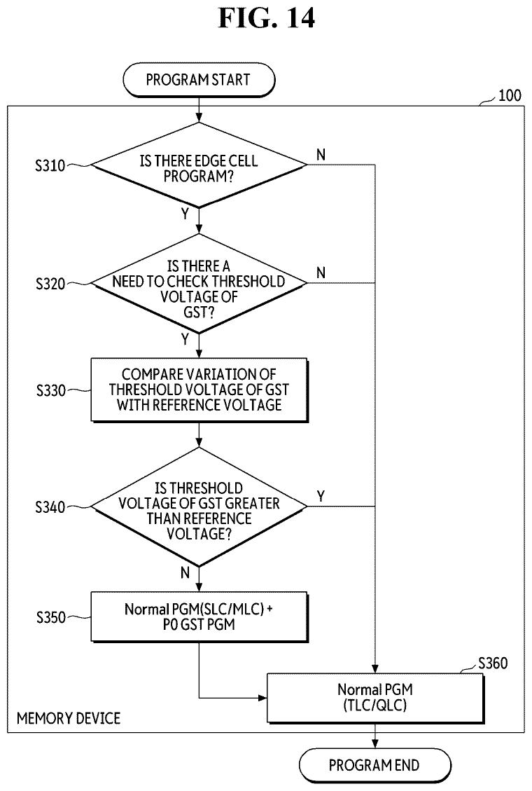

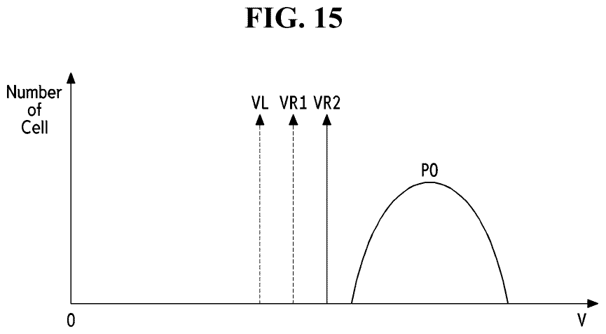

FIG. 14 is a flowchart for describing the operation of the memory system according to one or more embodiments. FIG. 15 is a diagram for describing the operation of FIG. 14.

Referring to FIG. 14, the program operation is started. For example, the memory device 100 may start the program operation by receiving a program command and an address to which data is to be programmed from the memory controller (200 of FIG. 1).

In one or more embodiments, the program command received by the memory device 100 may be, for example, a command for instructing to program the data to the memory cells MCT connected to WL1 to WLn shown in FIG. 4.

Next, it is determined whether the cell programmed by the program command is a memory cell disposed at the edge of the cell string in response to the program command (S310).

If the cell programmed by the program command is not a memory cell disposed at the edge of the cell string (S310-N), the P0 GST may not be programmed while performing the program operation by the program command. Therefore, the normal program is performed in accordance with the program command without performing the program on the P0 GST (S360).

If the cell programmed by the program command is a memory cell disposed at the edge of the cell string (S310-Y), the P0 GST may be programmed, while performing the program operation by the program command. Therefore, it is determined whether to check the threshold voltage of the P0 GST (S320).

In one or more embodiments, determining whether the cell programmed by the program command is a memory cell disposed at the edge of the cell string may be performed by various ways.

In one or more embodiments, the memory device 100 may determine whether the cell programmed by the program command is a memory cell disposed at the edge of the cell string on the basis of whether the received program command is a triple level cell (TLC) program.

As previously described referring to FIG. 6, the memory cells (e.g., memory cells MCT connected to WL3 to WLn-2) disposed at the center of the first and second cell strings CS1 and CS2 may be triple level cells (TLC) or quadruple level cells (QLC) that store 3 or more bits, and the memory cells (e.g., memory cells MCT connected to WL1 to WL2 or WLn-1 to WLn) disposed at the edges of the first and second cell strings CS1 and CS2 may be multi-level cells (MLC) or single level cells (SLC) that store 2 or less bits.

Therefore, if the received program command is a triple level cell (TLC) program, the memory device 100 may determine that the cell programmed by the program command is a cell disposed at the center of the cell string.

If the received program command is not the TLC program, the memory device 100 may determine that the cell programmed by the program command is a cell disposed at the edge of the cell string.

Furthermore, in one or more embodiments, if the received program command is at least one of the triple level cell (TLC) program and the quadruple level cell (QLC) program, the memory device 100 may determine that the cell programmed by the program command is a cell disposed at the center of the cell string.

If the received program command is at least one of the multi-level cell (MLC) program and the single level cell (SLC) program, the memory device 100 may determine that the cell programmed by the program command is cell disposed at the edge of the cell string.

Referring to FIG. 14, if it is determined that the threshold voltage of the P0 GST does not need to be checked (S320-N), the program on the P0 GST is not performed, and the normal program is performed in accordance with the program command (S360).

If it is determined to check P0 GST (S320-Y), the threshold voltage variation of P0 GST is compared with the reference voltage (S330).

In the case of one or more embodiments, if it is determined that the program on P0 GST is necessary, the program on P0 GST and the program on the edge cell of the cell string are performed simultaneously. That is, the program on P0 GST may be performed, while the program on the edge cell of the cell string is being performed.

Therefore, in order to ensure the reliability of the program operation on the edge cell of the cell string, the memory device 100 may compare a reference voltage VR2, which is higher than the first operating voltage (VL of FIG. 6) and higher than the reference voltage VR1, with the threshold voltage variation of P0 GST, as shown in FIG. 15. That is, by applying a stricter standard to the threshold voltage variation of P0 GST to manage the variation, it is possible to ensure the operational reliability when the program on P0 GST and the program on the edge cells of the cell string are performed simultaneously.

Next, if the threshold voltage variation of the P0 GST is greater than the reference voltage (S340-Y), the program on the P0 GST may not be performed. Therefore, the program on the P0 GST is not performed, and the normal program for programming the data in accordance with a program command is performed (S360).

If the threshold voltage variation of the P0 GST is not greater than the reference voltage (S340-N), the program on the P0 GST and the program on the edge cell of the cell string are performed simultaneously (S350).

The operations S320, S330, and S340 of the memory device 100 are substantially the same as those in one or more embodiments described above, and therefore the repeated description will not be provided.

In the case of one or more embodiments, because the program operation on the P0 GST may be performed in the same manner as other program operations of the memory device 100, the operating efficiency of the memory device 100 may be improved.

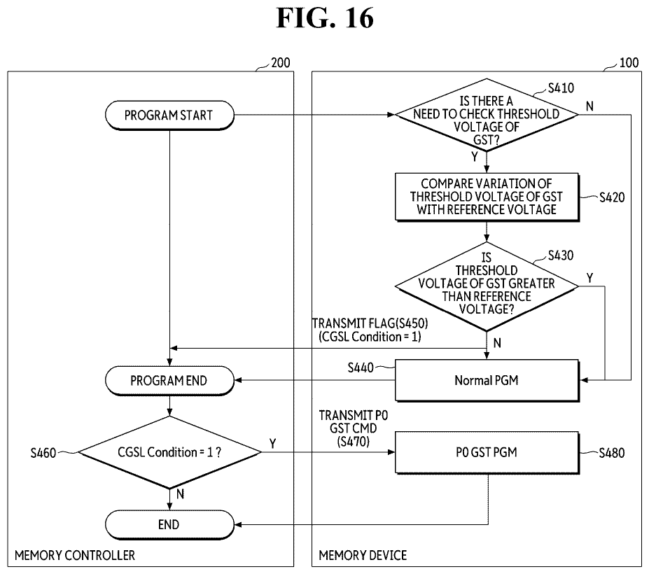

FIG. 16 is a flowchart showing the operation of a memory system according to one or more embodiments.

Referring to FIG. 16, a program operation is started. For example, the memory controller 200 may start the program operation by receiving a program command and an address to which the data is programmed from an external host.

In one or more embodiments, the program command received by the memory controller 200 may be, for example, a command for instructing to program the data to the memory cells MCT connected to WL1 to WLn shown in FIG. 4 of the memory device 100.

Next, the memory controller 200 instructs the memory device 100 to determine whether to check the threshold voltage of P0 GST based on the program command (S410).

If the memory device 100 determines that the threshold voltage of P0 GST does not need to be checked (S410-N), because it is not necessary to perform the program on P0 GST, after performing the normal program for programming the data in accordance with a program command (S440), the memory device 100 notifies the memory controller 200 that the program is completed.

If the memory device 100 determines to check P0 GST (S410-Y), it compares the threshold voltage variation of P0 GST with the reference voltage (S420).

If the threshold voltage variation of P0 GST is greater than the reference voltage (S430-Y), it is not necessary to perform the program on P0 GST. Therefore, the memory device 100 performs the normal program for programming the data in accordance with a program command (S440), and then notifies the memory controller 200 that the program is completed.

If the threshold voltage variation of P0 GST is not greater than the reference voltage (S430-N), it is necessary to perform the program on P0 GST. However, in one or more embodiments, instead of immediately performing the program on P0 GST, the memory device 100 notifies the memory controller 200 that the program on P0 GST is required.

For example, the memory device 100 may provide the memory controller 200 with a flag in which a CGSL condition value is set to 1 (S450). Further, the memory device 100 performs the normal program for programming the data in accordance with a program command (S440), and then notifies the memory controller 200 that the program is completed.

After that, the memory controller 200 checks a CGSL condition value of the flag received from the memory device 100 at an appropriate timing, taking into account the operating state of the memory device 100 (S460).

If the CGSL condition value of the flag received from the memory device 100 is not 1 (S460 -N), the operation ends without any additional operations.

On the other hand, if the CGSL condition value of the flag received from the memory device 100 is 1 (S460-Y), a command for instructing a program on P0 GST is generated on the basis of this, and the generated command is transmitted to the memory device 100 (S470). Further, the memory device 100 that received the command performs the program for controlling the variation of P0 GST (S480), and then notifies the memory controller 200 that the program is completed.

The operations S410, S420, S430, S440, and S480 of the memory device 100 are substantially the same as those in the above-mentioned embodiment, and therefore, the repeated description will not be provided.

In the case of one or more embodiments, the program operation on P0 GST may be performed in the same manner as other program operations of the memory device 100, or may be performed when the memory device 100 is idle, based on the instruction of the memory controller 200, taking into account the conditions of the memory device 100, thereby improving the operating efficiency of the memory device 100.

Even if the program operation on P0 GST is performed, the operation of the memory system is performed in accordance with the program sequence, and since it is not necessary to perform any additional operations while the memory block is being erased, it is easy to comply with specifications that stipulate the erase time. Also, according to the embodiment, because the program operation on some P0 GSTs may be performed during the program operation, and the program operation on the remaining P0 GSTs may be performed while the memory block is being erased, it is easy to comply with the specifications that stipulate the erase time.

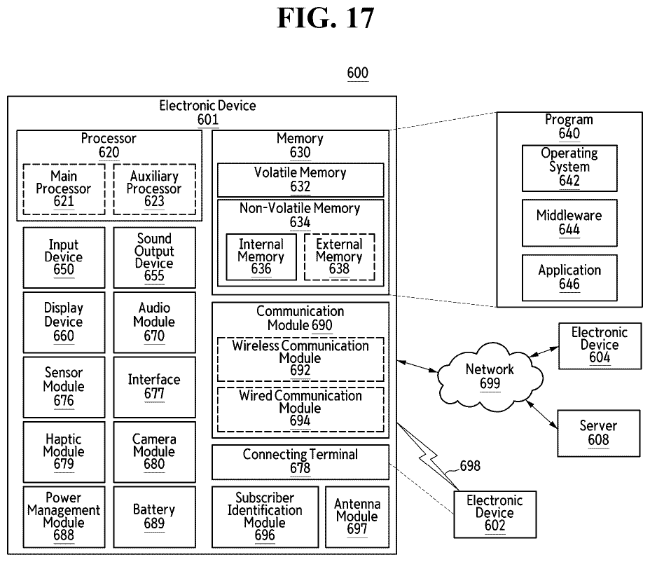

FIG. 17 is a block diagram of an electronic device according to one or more embodiments.

Referring to FIG. 17, an electronic device 601 inside a network environment 600 may communicate with an electronic device 602, for example, through a first network 698 such as a short-range wireless network, or may communicate with an electronic device 604 or a server 608, for example, through a second network 699 such as a long-range wireless network. In one or more embodiments, although such an electronic device 601 may be, for example, a notebook computer, a laptop computer, a portable mobile terminal, or the like, the embodiments are not limited thereto.

The electronic device 601 may communicate with the electronic device 604 through the server 608. The electronic device 601 may include a processor 620, a memory 630, an input device 650, a sound output device 655, an image display device 660, an audio module 670, a sensor module 676, an interface 677, a haptic module 679, a camera module 680, a power management module 688, a battery 689, a communication module 690, a subscriber identification module (SIM) 696, an antenna module 697, and the like.

In one or more embodiments, at least one of the components, for example, such as the display device 660 or the camera module 680, may be omitted from the electronic device 601, or one or more other components may be added to the electronic device.

In one or more embodiments, some of the components may be implemented as a single integrated circuit (IC). For example, the sensor module 676, such as a fingerprint sensor, an iris sensor or an illuminance sensor, may be buried in an image display device such as a display.

The processor 620 may execute software (e.g., program 640) for controlling other components of at least one electronic device 601, such as hardware or software component connected to the processor 620, thereby performing various date processes and computations.

As at least a part of data processes or computations, the processor 620 may load command or data received from other components such as the sensor module 676 or the communication module 690 to a volatile memory 632, process the command or data stored in the volatile memory 632, and store the resultant data in a non-volatile memory 634.

The processor 620 may include, for example, a main processor 621 such as a central processing unit (CPU) or an application processor (AP), and an auxiliary processor 623 that operates independently of the main processor 621 or operates in connection with the main processor 621.

Such an auxiliary processor 623 may include, for example, a graphic processing unit (GPU), an image signal processor (ISP), a sensor hub processor, a communication processor (CP) or the like.

In one or more embodiments, the auxiliary processor 623 may be configured to consume less power than the main processor 621 or perform specific functions. The auxiliary processor 623 may be separated from the main processor 621 or may be implemented as a part thereof.

The auxiliary processor 623 may control at least some of the functions or statuses associated with at least one component among the components of the electronic device 601, for example, on behalf of the main processor 621 while the main processor 621 is in an inactive status, or along with the main processor 621 while the main processor 621 is in an active status.

The memory 630 may store various types of data used in at least one component of the electronic device 601. The various types of data may include, for example, input data and output data for software such as program 640, and commands associated therewith. The memory 630 may include the volatile memory 632 and the non-volatile memory 634. The non-volatile memory 634 may include an internal memory 636 and an external memory 638. In one or more embodiments, the memory 630 may be implemented as the memory system described above.

The program 640 may be stored as software in the memory 630, and may include, for example, an operating system (OS) 642, a middleware 644 or an application 646.

The input device 650 may receive commands or data to be used in other components of the electronic device 601 from the outside of the electronic device 601. The input device 650 may include, for example, a microphone, a mouse or a keyboard.

The sound output device 655 may output a sound signal to the outside of the electronic device 601. The sound output device 655 may include, for example, a speaker. Multimedia data may be output through the speaker.

The image display device 660 may visually provide information to the outside of the electronic device 601. The image display device may include, for example, a display, a hologram device or a projector, and a control circuit for controlling the corresponding one among the display, the hologram device or the projector.

In one or more embodiments, the image display device 660 may include a touch circuit configured to detect the touch, or a sensor circuit, for example, such as a pressure sensor configured to measure strength of force caused by the touch.

The audio module 670 may convert the sound into an electrical signal or vice versa. In one or more embodiments, the audio module 670 may obtain the sound through the input device 650 or may output the sound through the sound output device 655 or through a headphone of the external electronic device 602 that is directly or wirelessly connected to the electronic device.

The sensor module 676 detects an operating status of the electronic device 601, for example, such as power or temperature, or an external environmental status of the electronic device 601, for example, such as a user's status, and may generate an electrical signal or data value corresponding to the detected status. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor or an illuminance sensor.

The interface 677 may support one or more specified protocols to be used by the electronic device 601 connected to the external electronic device 602 directly or wirelessly. In one or more embodiments, the interface 677 may include, for example, a high-resolution multimedia interface (HDMI), a universal serial bus (USB) interface, a secure digital (SD) card interface or an audio interface.

A connecting terminal 678 may include a connector through which the electronic device 601 may be physically connected to the external electronic device 602. In one or more embodiments, the connecting terminal 678 may include, for example, an HDMI connector, a USB connector, an SD card connector or an audio connector (e.g., a headphone connector or the like).

The haptic module 679 may convert an electrical signal into a mechanical stimulus, for example, such as vibration or motion that may be perceived by the user through a tactile sensation or a kinesthetic sensation. In one or more embodiments, the haptic module 679 may include, for example, a motor, a piezoelectric element or an electrical stimulator.

The camera module 680 may capture still images or moving images. In one or more embodiments, the camera module 680 may include one or more lenses, an image sensor, an image signal processor, a flash, and the like.

The power management module 688 may manage the power to be supplied to the electronic device 601. The power management module 688 may be implemented, for example, as at least a part of a power management integrated circuit (PMIC).

The battery 689 may supply power to at least one component of the electronic device 601. According to one or more embodiments, the battery 689 may include, for example, a non-rechargeable primary battery, a rechargeable secondary battery or a fuel cell.

The communication module 690 may support establishment of a direct communication channel or a wireless communication channel between the electronic device 601 and an external electronic device, for example, such as the electronic device 602, the electronic device 604 or the server 608, and may perform the communication through the established communication channel.

The communication module 690 may include one or more communication processors that are operable independently of the processor 620 and support a direct communication or a wireless communication.

In one or more embodiments, the communication module 690 may include a wireless communication module 692, for example, such as a cellular communication module, a short-range wireless communication module or a global navigation satellite system (GNSS) communication module, or a wired communication module 694, for example, such as a local area network (LAN) communication module or a power line communication module (PLC).

Among these communication modules, the corresponding communication module may communicate with the external electronic device through the first network 698, for example, such as a Bluetooth™, a WiFi (wireless-fidelity) direct or an IrDA (standard of the Infrared Data Association) or the second network 699, for example, such as a cellular communication network, an Internet or a long-range communication network

The various types of communication modules may be implemented as a single component or may be implemented as a plurality of components separated from each other. The wireless communication module 692 may verify and authenticate the electronic device 601 inside a communication network, such as the first network 698 or the second network 699, for example, using subscriber information such as an international mobile subscriber identifier (IMSI) stored in the subscriber identification module 696.

The antenna module 697 may transmit or receive signals or power to or from the outside of the electronic device 601. In one or more embodiments, the antenna module 697 may include one or more antennas, and hence, at least one antenna which is suitable for communication scheme used in communication networks such as the first network 698 or the second network 699 may be selected by the communication module 690. The signal or power may then be transmitted or received between the communication module and the external electronic device through at least one selected antenna.

At least some of the aforementioned components may be connected to each other to perform a signal communication between them through an inter-peripheral communication scheme, for example, such as a general purpose input and output (GPIO), a serial peripheral interface (SPI) or a mobile industry processor interface (MIPI).

In one or more embodiments, the command or data may be transmitted or received between the electronic device 601 and the external electronic device 606 through the server 608 connected to the second network 699. Each of the electronic devices 602 and 606 may be devices which are the same type as or different type from of the electronic device 601. All or some of the operations to be executed in the electronic device 601 may be executed in one or more external electronic devices 602, 606 or 608. For example, all or some of the operations to be executed in the electronic device 601 may be performed in one or more external electronic devices 602, 606 or 608.

For example, if the electronic device 601 needs to perform the functions or services automatically or in response to request from a user or other devices, the electronic device 601 that executes the functions or services may require one or more external electronic devices to perform at least some of the functions or services on behalf of this or additionally. One or more external electronic devices that receive the request may perform at least some of the requested function or service or additional functions or additional services associated with the request, and send the results of the execution to the electronic device 601. The electronic device 601 provides the results as at least a part of the response to the request, with or without accompanying further processing of the results. For example, cloud computing, distributed computing or client-server computing techniques may be used for this purpose.

Although the embodiments of the present invention have been described above with reference to the accompanying drawings, the present invention is not limited to the above embodiments, and may be fabricated in various different forms. Those skilled in the art will appreciate that the present invention may be embodied in other specific forms without changing the technical spirit or essential features of the present invention. Accordingly, the above-described embodiments should be understood in all respects as illustrative and not restrictive.

What is claimed is:

1. A memory device comprising:
a memory cell array comprising:
a cell string comprising a plurality of memory cells connected to a bit line and a common source line;
a first ground selection transistor having a first threshold voltage and configured to connect the common source line to the plurality of memory cells based on a voltage applied to a first ground selection line; and
a second ground selection transistor having a second threshold voltage greater than the first threshold voltage, and configured to connect the common source line to the plurality of memory cells based on a voltage applied to a second ground selection line; and
a control hardware configured to control an operation of the memory cell array, wherein the control hardware is further configured to:
receive a first program command for programming the plurality of memory cells;
determine whether to check a threshold voltage of the second ground selection transistor based on the first program command;
compare variation of the threshold voltage of the second ground selection transistor with a reference voltage based on determining to check the threshold voltage of the second ground selection transistor; and
program the threshold voltage of the second ground selection transistor based on a result of the comparing.

2. The memory device of claim 1, wherein the control hardware is further configured to:
receive a first block address of data to be programmed using the first program command;
receive a second program command, and a second block address of data to be programmed using the second program command, after receiving the first program command;
and determine whether to check the threshold voltage of the second ground selection transistor, based on whether the first block address and the second block address indicate a same block.

3. The memory device of claim 1, wherein the control hardware is further configured to:
determine whether a command received before the first program command is an erase command; and
determine whether to check the threshold voltage of the second ground selection transistor, based on determining that the command received before the first program command is not the erase command.

4. The memory device of claim 1, wherein the control hardware is further configured to:
compare a reference time with an interval between the first program command and an erase command received before the first program command; and
determine to check the threshold voltage of the second ground selection transistor based on the interval being equal to or greater than the reference time.

5. The memory device of claim 4, wherein the control hardware comprises a clock counter, and the control hardware is further configured to:
count a number of cycles between the erase command and the first program command, using the clock counter;
compare the counted number of cycles with a reference number of cycles; and
determine to check the threshold voltage of the second ground selection transistor, based on the counted number of cycles being equal to or greater than the reference number of cycles.

6. The memory device of claim 1, wherein the control hardware is further configured to:
determine whether a memory cell to be programmed based on the first program command is at an edge of the cell string,
wherein the determining whether to check the threshold voltage of the second ground selection transistor is based on determining that the memory cell to be programmed is at the edge of the cell string.

7. The memory device of claim 6, wherein the control hardware is further configured to:
determine that the memory cell to be programmed based on the first program command is not at the edge of the cell string, based on the first program command being a TLC (triple level cell) program; and
determine that the memory cell to be programmed based on the first program command is at the edge of the cell string based on the first program command not being the TLC program.

8. The memory device of claim 6,
wherein the control hardware is further configured to program the threshold voltage of the second ground selection transistor while programming the memory cell at the edge of the cell string.

9. The memory device of claim 1,
wherein the control hardware is further configured to apply an operating voltage, which turns on the first ground selection transistor and turns off the second ground selection transistor, to at least one of the first ground selection line and the second ground selection line, and
wherein the reference voltage is greater than the operating voltage.

10. The memory device of claim 1,
wherein the control hardware is further configured to check the threshold voltage of the second ground selection transistor based on receiving a flag from a memory controller.

11. The memory device of claim 1, wherein the control hardware is further configured to:
transmit a flag to a memory controller after programming at least one memory cell among the plurality of memory cells based on the first program command;
receive a first command generated based on the transmitted flag from the memory controller; and
program the threshold voltage of the second ground selection transistor based on the received first command.

12. A method of operating a memory device comprising a cell string comprising a plurality of memory cells connected to a bit line and a common source line, a first ground selection transistor having a first threshold voltage and configured to connect the common source line to the plurality of memory cells based on a voltage applied to a first ground selection line, and a second ground selection transistor having a second threshold voltage greater than the first threshold voltage, and configured to connect the common source line to the plurality of memory cells based on a voltage applied to a second ground selection line, the method comprising:
receiving a first program command for programming the plurality of memory cells;
determining whether to check the threshold voltage of the second ground selection transistor based on the first program command;
comparing variation of the threshold voltage of the second ground selection transistor with a reference voltage based on determining to check; and
programming the threshold voltage of the second ground selection transistor based on a result of the comparing.

13. The method of operating the memory device of claim 12, further comprising:
receiving a first block address of data to be programmed using the first program command;
receiving a second program command, and a second block address of data to be programmed using the second program command, before receiving the first program command,
wherein the determining whether to check the threshold voltage of the second ground selection transistor is based on whether the first block address and the second block address indicate a same block.

14. The method of operating the memory device of claim 12, further comprising:
determining whether a command received before the first program command is an erase command,
wherein the determining whether to check the threshold voltage of the second ground selection transistor needs to be checked is based on determining that the command received before the first program command is not the erase command.

15. The method of operating the memory device of claim 12, further comprising:
comparing a reference time with an interval between an erase command received before the first program command and the first program command; and
determining to check the threshold voltage of the second ground selection transistor based on the interval being equal to or greater than the reference time.

16. The method of operating the memory device of claim 12, further comprising:
applying an operating voltage, which turns on the first ground selection transistor and turns off the second ground selection transistor, to at least one of the first ground selection line and the second ground selection line,
wherein the reference voltage is greater than the operating voltage.

17. A memory system comprising:
a cell string comprising:
a plurality of memory cells connected to a bit line and a common source line;
a first ground selection transistor having a first threshold voltage and configured to connect the common source line to the plurality of memory cells based on a voltage applied to a first ground selection line; and
a second ground selection transistor having a second threshold voltage greater than the first threshold voltage, and configured to connect the common source line to the plurality of memory cells based on a voltage applied to a second ground selection line; and
a memory controller configured to control operation of a memory device, wherein the memory controller is further configured to:
receive a program command for programming the plurality of memory cells; and
determine whether to check the threshold voltage of the second ground selection transistor based on the program command,
wherein the memory device is configured to:
compare variation of the threshold voltage of the second ground selection transistor with a reference voltage based on the memory controller determining to check the threshold voltage of the second ground selection transistor; and
program the threshold voltage of the second ground selection transistor based on a result of the comparing.

18. The memory system of claim 17,
wherein the memory controller is further configured to:
compare a reference time with an interval between an erase command received before the program command and the program command;
determine to check the threshold voltage of the second ground selection transistor based on the interval being equal to or greater than the reference time; and
transmit a flag to the memory device based on the determining to check the threshold voltage of the second ground selection transistor;
wherein the memory device is further configured to compare the variation of the threshold voltage of the second ground selection transistor with the reference voltage based on the transmitted flag.

19. The memory system of claim 17,
wherein the memory device is further configured to transmit a flag to the memory controller after programming at least one memory cell among the plurality of memory cells, based on the memory controller receiving the program command,
wherein the memory controller is further configured to transmit a first command to the memory device based on the transmitted flag, and
wherein the memory device is further configured to program the threshold voltage of the second ground selection transistor based on the first command received from the memory controller.

20. The memory system of claim 19,
wherein the memory controller is further configured to transmit the first command to the memory device based on an operating state of the memory device.
